(19) United States
(12) Patent Application Publication
(10) Pub. No.: US 2009/0153216 A1
(43) Pub. Date: Jun. 18, 2009

(54) IO DRIVER CIRCUIT WITH OUTPUT STAGE CONFIGURABLE AS A THEVENIN TERMINATOR

(75) Inventors: David Jia Chen, Endwell, NY (US); William Frederick Lawson, Vestal, NY (US)

Correspondence Address: WOOD, HERRON & EVANS, L.L.P. (IBM), 2700 CAREW TOWER, 441 VINE STREET, CINCINNATI, OH, 45202, US

(73) Assignee: INTERNATIONAL BUSINESS MACHINES CORPORATION, Armonk, NY (US)

(21) Appl. No.: 11/955,023

(22) Filed: Dec. 12, 2007

(51) Int. Cl. H03L 5/00

(52) U.S. Cl. 327/308

(57) ABSTRACT

An IO driver circuit incorporates an output stage control circuit that selectively configures an output stage for the IO driver circuit to operate as a thevenin termination whenever the IO driver circuit is receiving a signal from an input/output node to which the IO driver circuit is coupled. The output stage may include a plurality of branches, with each branch having a pull-up device and a pull-down device, and the output stage control circuit selectively activates the pull-up devices in a first subset of branches in the output stage while concurrently activating the pull-down devices in a second subset of branches, as well as while leaving the pull-up devices in the second subset of branches and the pull-down devices in the first subset of branches deactivated.

### FIELD OF THE INVENTION

The invention is generally related to circuit arrangements, and in particular to input/output (IO) driver circuit arrangements.

### BACKGROUND OF THE INVENTION

Communication on and off an integrated circuit device, or chip, often requires the use of an IO driver circuit for each pin, or interconnect, of the chip (alternatively referred to as a pad). An IO driver circuit for a bidirectional pin includes a receiver circuit that handles the reception of data from a transmission line and a driver circuit that handles the output of data to the transmission line.

For a driver circuit, it is often important to carefully control the output impedance of the circuit for the purpose of impedance matching with a load. When the output impedance of a driver circuit is mismatched with that of its load, the fidelity of the signal being transmitted can degrade due to reflections and distortions of the signal.

Likewise, for a receiver circuit, the receiver circuit acts as a load, and similarly must be matched with a circuit driving the transmission line to minimize similar effects. For this reason, receiver circuits often incorporate terminations that serve to control the characteristic impedance of the receiver circuit. One such type of termination that is commonly used in a receiver circuit is a thevenin terminator. One type of thevenin terminator, for example, incorporates one or more pull-up devices coupled between the input of the receiver and positive power, as well as one or more pull-down devices coupled between the input of the receiver and ground, which collectively operate as resistive elements when active.

Matching both the output impedance of the driver circuit and the input impedance of the receiver circuit with the impedance of the transmission line is often critical to maintain signal integrity during data transmission on and off a chip by an IO driver circuit. However, the variety and size of devices required to calibrate either the driver output stage or the receiver termination of a conventional IO driver often lead to a large and unduly complex design during the physical design stage, and on space-constrained designs, it becomes difficult to squeeze both layouts into one design. Therefore, a significant need exists in the art for a manner of simplifying and reducing the layout of an IO driver.

### SUMMARY OF THE INVENTION

The invention addresses these and other problems associated with the prior art by providing a design for an IO driver circuit that incorporates an output stage control circuit that selectively configures an output stage for the IO driver circuit to operate as a thevenin termination whenever the IO driver circuit is receiving a signal from an input/output node to which the IO driver circuit is coupled. In some embodiments consistent with the invention, for example, an output stage includes a plurality of branches, with each branch having a pull-up device and a pull-down device. The output stage control circuit selectively activates the pull-up devices in a first subset of branches in the output stage while concurrently activating the pull-down devices in a second subset of branches, as well as while leaving the pull-up devices in the second subset of branches and the pull-down devices in the first subset of branches deactivated, whenever the IO driver circuit is receiving a signal from the input/output node. By doing so, the activated pull-up devices in the first subset of branches combine with the activated pull-down devices in the second subset of branches to provide a calibrated and controlled impedance at the input/output node during signal reception.

Consistent with one aspect of the invention, for example, a circuit arrangement includes an input/output node, a receiver circuit comprising an input configured to receive an input signal from the input/output node, and a driver circuit comprising an input and an output, with the output configured to output an output signal to the input/output node responsive to an input signal received at the input, and with the driver circuit comprising an output stage coupled between the input and the output of the driver circuit. The output stage includes first, second, third and fourth branches coupled in parallel to one another, with each branch including a pull-up device and a pull-down device coupled to the output. The circuit arrangement also includes an output stage control circuit coupled to the output stage to selectively configure the output stage to operate as a thevenin termination for the input/output node when the receiver circuit is receiving the input signal. The output stage control circuit configures the output stage to operate as a thevenin termination by concurrently activating the pull-up devices in the first and second branches and the pull-down devices in the third and fourth branches, while deactivating the pull-up devices in the third and fourth branches and the pull-down devices in the first and second branches.

These and other advantages and features, which characterize the invention, are set forth in the claims annexed hereto and forming a further part hereof. However, for a better understanding of the invention, and of the advantages and objectives attained through its use, reference should be made to the Drawings, and to the accompanying descriptive matter, in which there is described exemplary embodiments of the invention.

### BRIEF DESCRIPTION OF THE DRAWINGS

FIG. 1 is a schematic diagram of an IO driver circuit arrangement incorporating a configurable output stage termination technique consistent with the invention.

FIG. 2 is a schematic diagram of a driver enable circuit configured to generate enable signals utilized by the IO driver circuit arrangement of FIG. 1.

### DETAILED DESCRIPTION

Embodiments consistent with the invention utilize a configurable output stage for an IO driver circuit that is capable of functioning as a thevenin termination when the IO driver circuit is receiving a data signal over a transmission line. Embodiments of the invention utilize a driver output stage that includes a plurality of parallel pull-up and pull-down branches. While driving a logic 1 signal, the pull-up devices in the plurality of branches are enabled, and while driving a logic 0 signal, the pull-down devices in the plurality of branches are used.

Additional output stage control logic is incorporated into the driver output stage so that while the driver is disabled, the pull-up devices in a first subset of branches and the pull-down devices in a second subset of branches are enabled, while the pull-down devices in the first subset of branches and the pull-up devices in the second subset of branches are disabled. It will be appreciated that the first and second subsets of branches may not be overlapping (i.e., no branch may be a member of both subsets) and that the first and second subsets of branches may collectively incorporate all branches in the output stage.

So configured with the pull-up devices in the first subset of branches and the pull-down devices in the second subset of branches enabled, the output stage operates as a thevenin termination, eliminating the need for a relatively large area otherwise required for a separate thevenin terminator stage for the receiver and the circuits needed to turn on the terminator. In addition, embodiments consistent with the invention have a lower receiver input pin capacitance due to the elimination of the additional devices that would otherwise be required to provide a separate receiver termination.

In the illustrated embodiment, the driver output stage is comprised of four parallel pull-up and pull-down branches. While driving a logic 1 signal, the pull-up branches are enabled, and while driving a logic 0 signal, the pull-down branches are used. Additional logic is incorporated into the driver output stage so that while the driver is disabled, two of the pull-up branches and two of the pull-down branches are enabled.

It will be appreciated, however, that any number of branches may be utilized in an IO driver circuit consistent with the invention, and furthermore, that any number of pull-up and/or pull-down devices may be selectively enabled when a driver output stage is configured to operate as a thevenin terminator. The selection of the number of branches to incorporate in a driver output stage, as well as the number of pull-up and/or pull-down devices that are activated in order to configure the driver output stage as a thevenin terminator, will vary depending upon a number of factors, including the desired thevenin termination impedance, the characteristic impedance of each pull-up and pull-down device, signal skew tolerances, etc. Selection of appropriate numbers of branches and devices to activate to form a thevenin terminator are well within the abilities of one of ordinary skill in the art having the benefit of the instant disclosure.

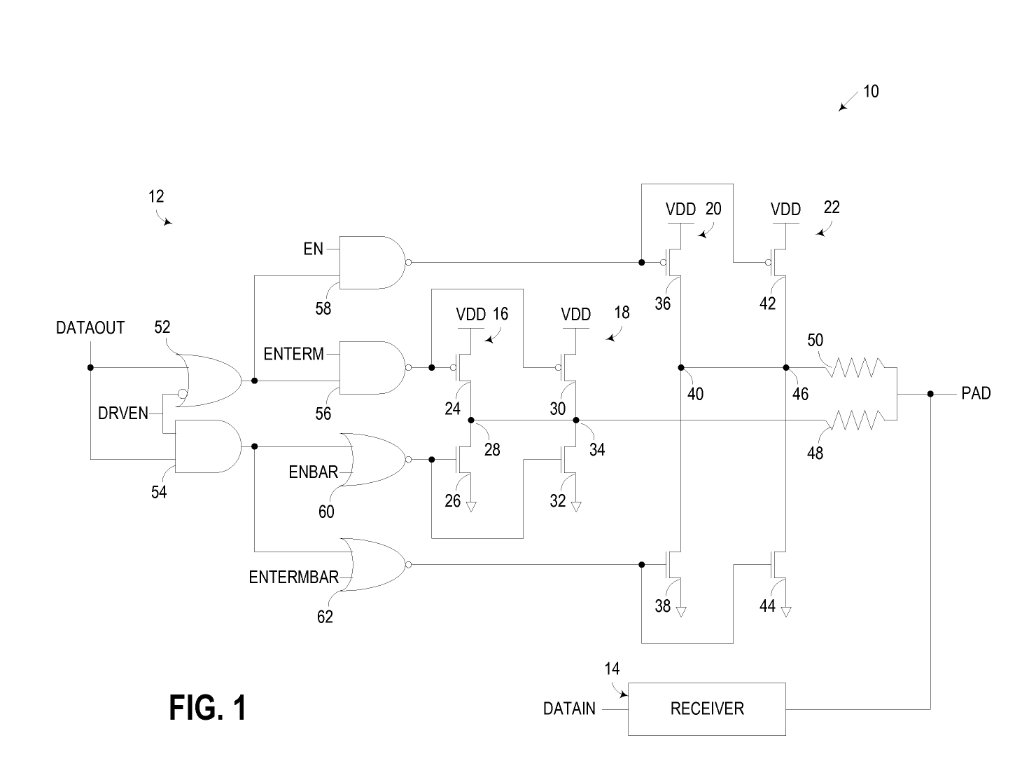

Now turning to the drawings, wherein like numbers denote like parts throughout the several views, FIG. 1 illustrates an exemplary IO driver circuit arrangement 10 incorporating a driver output stage that is configurable to operate as a thevenin termination. Circuit arrangement 10 includes a driver circuit 12 and a receiver circuit 14. Driver circuit 12 includes an input that receives a DATAOUT input signal and an output coupled to a PAD input/output node, and incorporates intermediate the input and output an output stage with first, second, third and fourth pull-up/pull-down branches 16, 18, 20 and 22. Receiver circuit 14 includes an input coupled to receive a data signal from the PAD input/output node and output that signal as a DATAIN signal at an output thereof. Receiver circuit 14 is not described in further detail herein, as practically any receiver design may be used to receive signals on the PAD input/output node, the use and configuration of which would be known to one of ordinary skill in the art having the benefit of the instant disclosure.

First branch 16 of driver circuit 12 includes a pull-up device 24 and pull-down device 26 coupled to a common node 28. Pull-up device 24 is coupled between positive power (VDD) and node 28, and is implemented as a p-type field effect transistor (PFET), which is active when the signal applied to its gate is low (logic “0”). Pull-down device 26 is coupled between node 28 and ground, and is implemented as an n-type field effect transistor (NFET), which is active when the signal applied to its gate is high (logic “1”).

Similarly, branches 18, 20 and 22 include pull-up devices 30, 36 and 42 and pull-down devices 32, 38 and 44 coupled to one another at common nodes 34, 40 and 46. Nodes 28 and 34 are coupled to one another, and are coupled to an output of the driver circuit, as well as to a PAD input/output node for the IO driver circuit, via a first resistor 48. Similarly, nodes 40 and 46 are coupled to one another, and are coupled to the output of the driver circuit, as well as to the PAD input/output node for the IO driver circuit, via a second resistor 50. Resistors 48, 50 operate to linearize the driver and termination impedance and increase the tolerance for the impedance due to pull-up/pull-down device variability. Each resistor 48, 50 also provides a path of resistance for the PAD input/output node to both VDD and ground, and each functions as a protective device for ESD events.

Driver circuit 12 receives as input a DATAOUT signal, representing the input signal to be output over the PAD input/output node by the driver, which is passed as an input to an OR gate 52 and an AND gate 54. A driver enable (DRVEN) signal is also provided as an input to OR gate 52 and AND gate 54, with the DRVEN signal inverted at the input to OR gate 52. The output of OR gate 52 is provided as an input to two NAND gates, NAND gate 56 and NAND gate 58. The output of AND gate 54 is provided as input to two NOR gates 60, 62.

NAND gate 56 receives as another input a first enable signal, designated ENTERM, while NAND gate 58 receives as another input a second enable signal, designated EN. NAND gate 56 drives the gate inputs of PFETs 24 and 30 in first and second branches 16, 18, while NAND gate 58 drives the gate inputs of PFETs 36, 42 in third and fourth branches 20, 22. The first enable signal ENTERM is configured to be asserted whenever the driver circuit is activated, as well as whenever the driver circuit is configured to operate as a thevenin terminator when the driver circuit is otherwise deactivated and the receiver circuit is activated (i.e., when the IO driver circuit is receiving data on the input/output node). The second enable signal EN is configured to be asserted whenever the driver circuit is activated. Whenever the driver circuit is deactivated (e.g., whenever the receiver circuit is activated), the EN signal is deasserted.

NOR gate 60 receives as another input an inverted second enable signal, designated ENBAR, while NOR gate 62 receives as another input an inverted first enable signal, designated ENTERMBAR. NOR gate 60 drives the gate inputs of NFETs 26 and 32 in first and second branches 16, 18, while NOR gate 62 drives the gate inputs of NFETs 38, 44 in third and fourth branches 20, 22.

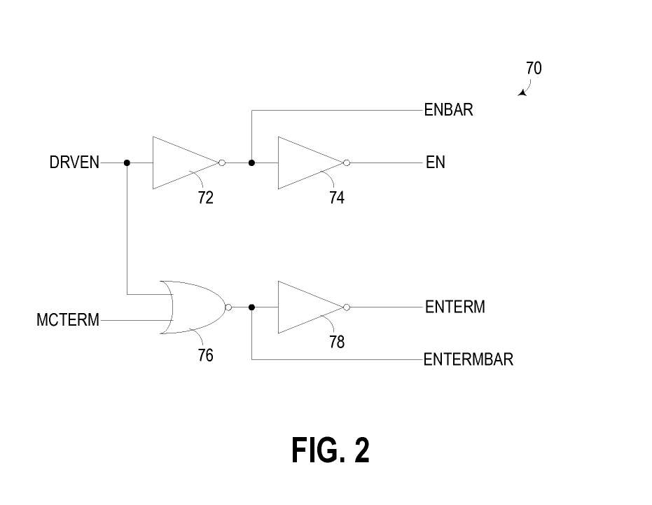

FIG. 2 illustrates an enable signal generation circuit 70 that is used to generate the ENTERM and EN signals (and their respective inverted representations ENTERMBAR and ENBAR). In order to generate the EN and ENBAR signals, the DRVEN signal is supplied to an inverter 72, which outputs the ENBAR inverted second enable signal, and which drives an inverter 74, which outputs the EN second enable signal. It will be appreciated that the EN signal is logically equivalent to the DRVEN signal, and as such, in some embodiments the DRVEN signal may drive NAND gate 58 (FIG. 1) directly.

The DRVEN signal is also supplied as an input to a NOR gate 76, which performs a logical NOR with an MCTERM signal and outputs the ENTERMBAR inverted first enable signal, and which drives an inverter 78, which outputs the ENTERM second enable signal. The MCTERM signal is used to selectively configure the driver to operate as a thevenin terminator whenever the receiver circuit is active.

The states of the DRVEN and MCTERM signals determine the mode of the driver output stage. Whenever the DRVEN input is high, the state of MCTERM is a “don't care” and the driver is active. When DRVEN is high, the logic that combines DATAOUT and DRVEN (OR gate 52 and AND gate 54) will just pass the state of DATAOUT to NANDs 56, 58, which control PFET pull-up devices 24, 30, 36, 42, and to NORs 60, 62, which control the NFET pull-down devices 26, 32, 38, 44. In the normal driver operation mode, a high state on DATAOUT will enable pull-up devices 24, 30, 36, 42 and disable pull-down devices 26, 32, 38, 44, and a low state on DATAOUT will disable pull-up devices 24, 30, 36, 42 and enable pull-down devices 26, 32, 38, 44.

If DRVEN and MCTERM are low, the output stage is disabled. Neither pull-up nor pull-down devices are active. If, however, MCTERM is high and DRVEN is low, the output stage is used as a thevenin terminator. The logic that combines DATAOUT and DRVEN (OR gate 52 and AND gate 54) drives a 1 to one of the inputs of both NANDs 56, 58 and drives a 0 to one of the inputs of both NORs 60, 62. As a result, the state of EN, ENBAR, ENTERM, and ENTERMBAR determine which pull-up and pull-down devices are activated. Since DRVEN is low, EN will be low and ENBAR will be high, which disables PFETs 36, 42 of third and fourth branches 20, 22 and NFETs 26, 32 of first and second branches 16, 18. Because MCTERM is high, ENTERM is high and ENTERMBAR is low. This enables PFETs 24, 30 of first and second branches 16, 18 and NFETs 38, 44 of third and fourth branches 20, 22. Consequently, active PFET devices 24, 30 and active NFET devices 38, 44 form a thevenin termination.

Which of the pull-up or pull-down devices is enabled by this logic can vary in different implementations. Because only two of the pull-up and two of the pull-down devices are enabled, the impedances on both the pull-up and pull-down side are 2× the calibrated driver output stage, and as such, the thevenin termination impedance is the same as the calibrated driver output impedance.

When designing a thevenin terminator, the impedance to VDD and the impedance to ground are 2× the target thevenin impedance. Consequently, if the calibrated driver output stage is tuned for 50 ohms, each branch may be calibrated for 200 ohms. When the output stage is configured to operate as a thevenin termination, two pull-up devices and two pull-down devices are activated at the same time, and consequently there is 100 ohms to VDD and 100 ohms to ground, resulting in a 50 ohm thevenin terminator.

Various modifications may be made without departing from the spirit and scope of the invention. For example, different devices sizes, different devices (e.g., non-FET devices), different numbers of branches, etc., may be used to implement the herein described configurable output stage termination technique. Other circuit modifications, consistent with the general principles disclosed, will be appreciated by one of ordinary skill in the art. Therefore, the invention lies in the claims hereinafter appended.

What is claimed is:

1. A circuit arrangement, comprising:
an input/output node;
a receiver circuit comprising an input configured to receive an input signal from the input/output node;
a driver circuit comprising an input and an output, the output configured to communicate an output signal to the input/output node responsive to an input signal received at the input, the driver circuit comprising an output stage coupled between the input and the output of the driver circuit, the output stage including first, second, third and fourth branches coupled in parallel to one another, each branch including a pull-up device and a pull-down device coupled to the output; and
an output stage control circuit coupled to the output stage to selectively configure the output stage to operate as a thevenin termination for the input/output node when the receiver circuit is receiving the input signal, wherein the output stage control circuit configures the output stage to operate as a thevenin termination by concurrently activating the pull-up devices in the first and second branches and the pull-down devices in the third and fourth branches, while deactivating the pull-up devices in the third and fourth branches and the pull-down devices in the first and second branches.

2. The circuit arrangement of claim 1, wherein the each of the pull-up devices is a PFET device coupled between the output of the driver circuit and VDD, and wherein each of the pull-down devices is an NFET device coupled between the output of the driver circuit and ground.

3. The circuit arrangement of claim 2, further comprising first and second NAND gates, the first NAND gate having a first input coupled to receive a first enable signal, a second input coupled to receive the input signal, and an output coupled to gate inputs of the pull-up devices in the first and second branches, and the second NAND gate having a first input coupled to receive a second enable signal, a second input coupled to receive the input signal, and an output coupled to gate inputs of the third and fourth branches.

4. The circuit arrangement of claim 3, further comprising first and second NOR gates, the first NOR gate having a first input coupled to receive an inverted second enable signal, a second input coupled to receive the input signal, and an output coupled to gate inputs of the pull-down devices in the first and second branches, and the second NOR gate having a first input coupled to receive an inverted first enable signal, a second input coupled to receive the input signal, and an output coupled to gate inputs of the pull-down devices in the third and fourth branches.

5. The circuit arrangement of claim 4, further comprising an OR gate and an AND gate, the OR gate coupled intermediate the input of the driver circuit and the second inputs of the first and second NAND gates and configured to drive the input signal high at the second inputs of the first and second NAND gates when the output stage is configured to operate as a thevenin termination, and the AND gate coupled intermediate the input of the driver circuit and the second inputs of the first and second NOR gates and configured to drive the input signal low at the second inputs of the first and second NOR gates when the output stage is configured to operate as a thevenin termination.

6. The circuit arrangement of claim 2, further comprising first and second resistors, the first resistor coupled intermediate a common node of the pull-up and pull-down devices in the first and second branches and the input/output node, and the second resistor coupled intermediate a common node of the pull-up and pull-down devices in the third and fourth branches and the input/output node.

7. A circuit arrangement, comprising:
an input/output node;
a receiver circuit comprising an input configured to receive an input signal from the input/output node;
a driver circuit comprising an input and an output, the output configured to output an output signal to the input/output node responsive to an input signal received at the input, the driver circuit comprising an output stage coupled between the input and the output of the driver circuit, the output stage including a plurality of branches coupled in parallel to one another, each branch including a pull-up device and a pull-down device coupled to the output; and
an output stage control circuit coupled to the output stage to selectively configure the output stage to operate as a thevenin termination for the input/output node when the receiver circuit is receiving the input signal, wherein the output stage control circuit configures the output stage to operate as a thevenin termination by concurrently activating the pull-up devices in a first subset of branches and the pull-down devices in a second subset of branches, while deactivating the pull-up devices in the second subset of branches and the pull-down devices in the first subset of branches.
